(19) United States
(12) Patent Application Publication
(10) Pub. No.: US 2026/0130043 A1
(43) Pub. Date: May 7, 2026

(54) PASSIVATING PEROVSKITE OPTOELECTRONIC DEVICES

(71) Applicant: Northwestern University, Evanston, IL (US)

(72) Inventors: Mercouri G. Kanatzidis, Wilmette, IL (US); Edward Hartley Sargent, Glencoe, IL (US); Bin Chen, Evanston, IL (US); Cheng Liu, Evanston, IL (US); Yi Yang, Evanston, IL (US)

(21) Appl. No.: 19/375,634

(22) Filed: Oct. 31, 2025

Related U.S. Application Data
(60) Provisional application No. 63/715,373, filed on Nov. 1, 2024.

(51) Int. Cl. H10K 30/88; H10K 30/50; H10K 85/50

(52) U.S. Cl. CPC H10K 30/88; H10K 30/50; H10K 85/50

(57) ABSTRACT

Perovskite optoelectronic devices, e.g., solar cells, are provided, which comprise a perovskite layer comprising a perovskite; and chemical passivating ligands bound to the perovskite of the perovskite layer, wherein the chemical passivating ligands comprise a thioether group, —SR′, wherein R′ is an alkyl group.

### CROSS-REFERENCE TO RELATED APPLICATION

The present application claims priority to U.S. Provisional Patent Application No. 63/715,373, filed on Nov. 1, 2024, the entire contents of which are incorporated herein by reference.

### REFERENCE TO GOVERNMENT RIGHTS

This invention was made with government support under 70NANB1911005 awarded by the National Institute of Standards and Technology. The government has certain rights in the invention.

### BACKGROUND

Certified power conversion efficiencies (PCEs)>25% have been widely reported for perovskite solar cells (PSCs) in the regular (n-i-p) structure. Although inverted (p-i-n) PSCs have potential advantages because of their stability, low-temperature processing, and compatibility with integration into tandem solar cells, their reported PCEs rarely surpass 24% under the stringent quasi-steady-state (QSS) protocol.

### SUMMARY

Perovskite optoelectronic devices, e.g., solar cells, are provided, which comprise a perovskite layer and passivating ligands bound thereto. The passivating ligands comprise chemical passivating ligands and, in embodiments according to a dual passivation scheme, may further comprise field-effect passivating ligands. The Example below describes an illustrative dual passivation scheme in which methylthio molecules were used to passivate surface defects and suppress recombination through strong coordination and hydrogen bonding, along with diammonium molecules to repel minority carriers and reduce contact-induced interface recombination achieved through field-effect passivation. The approach led to a fivefold increase in carrier lifetime and a threefold reduction in photoluminescence quantum yield loss. This approach enabled a certified quasi-steady-state PCE of 25.1% for inverted PSCs with stable operation at 65° C. for >2,000 hours in ambient air. Monolithic all-perovskite tandem solar cells were also fabricated with 28.1% PCE.

Embodiments of a perovskite optoelectronic device are provided that comprise a perovskite layer comprising a perovskite; and chemical passivating ligands bound to the perovskite of the perovskite layer, wherein the chemical passivating ligands comprise a thioether group, —SR′, wherein R′ is an alkyl group.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings, wherein like numerals denote like elements.

FIGS. 1A-1D. Passivation at the perovskite/ETL interface. FIGS. 1A, 1B show a schematic of the perovskite surface without passivation (FIG. 1A) and with both chemical and field-effect passivation (FIG. 1i). FIG. 1C shows chemical structures of the diammonium and ammonium ligands investigated in the Example, below. FIG. 1D shows PCEs of control vs. passivated PSCs using different passivation ligands and combinations thereof.

FIGS. 2A-2H. The process of passivation through the methylthio group on perovskite surfaces. FIG. 2A shows binding energies of ammonium ligands with clean and defective perovskite surfaces with the typical iodide vacancy. FIG. 2B shows electrostatic potential (p) of 3MTPA and AA ligands. FIG. 2C shows calculated charge density difference of anchoring ammonium ligands onto the perovskite surface with I vacancies. The open circles indicate the positions of I vacancies. The atoms in the structures are differentiated by different shading. FIG. 2D shows calculated charge density difference showing the hydrogen bond formation between 3MTPA and FA. FIG. 2E shows the proton NMR spectra of FAI, FAI with AAI, and FAI with 3MTPAI. FIG. 2F shows high-resolution Pb 4f XPS peaks of the perovskite films. FIG. 2G shows SIMS mapping of signal ratios of 3MTPA:PDA and AA:PDA for perovskite samples with PDAI₂/3MTPAI (1:2 molar ratio) and PDAI₂/AAI (1:2 molar ratio) bimolecular passivation. FIG. 2H shows PL intensity distribution of the 1 cm by 1 cm perovskite film post-synthetic treated by spray coating with ink 1 of PDAI₂/3MTPAI and ink 2 of PDAI₂/AAI solution centered around the diagonal corners.

FIGS. 3A-3E. Diammonium-methylthio dual passivation DMDP strategy working principle. FIG. 3A shows GIWAXS patterns of the control and DMDP-based perovskite films. FIG. 3B shows TRPL of the perovskite films treated with different ligands. FIG. 3C shows the energy level difference between the conduction band maximum and Fermi level for the perovskite films treated with different ligands. FIG. 3D shows ligand-concentration-dependent PLQY of the perovskite films, PLQY loss of the perovskite films after C₆₀ deposition, and PCEs of devices. For DMDP, the concentration of 3MTPAI was varied, while the PDAI₂ concentration was optimized and maintained at 6 mM. FIG. 3E is a schematic diagram showing the inhibition of interface recombination by PDAI₂ and the suppression of defect-induced recombination by 3MTPAI.

FIGS. 4A-4H. Device performance and stability. FIG. 4A shows J-V characteristics of the best-performing DMDP-based device. FIG. 4B shows a QSS J-V curve of one representative DMDP-based device certified at NREL. FIG. 4C shows certified QSS and fast-scan PCE statistics of inverted PSCs. FIG. 4D shows thermal stability of encapsulated PSCs annealed at 85° C. in nitrogen. FIG. 4E shows operational stability of encapsulated PSCs under constant one sun illumination at 65° C. in air with 50% RH. FIG. 4F shows PCEs of the WBG and NBG PSCs showing the universality of the DMDP strategy. FIG. 4G shows architecture of the tandem device. FIG. 4H shows J-V characteristics of the best-performing tandem device based on the DMDP strategy. The inset shows the stabilized PCE under MPPT.

### DETAILED DESCRIPTION

Perovskite optoelectronic devices are provided, which comprise a perovskite layer and passivating ligands bound thereto. The passivating ligands may be located at an interface formed between the perovskite layer and another functional layer of the optoelectronic device, e.g., an electron transport layer, as further described below. The passivating ligands may be characterized as being in the form of a passivating layer at this interface.

Although a variety of perovskite optoelectronic devices (e.g., light-emitting diodes, lasers, detectors, sensors) may be used, in embodiments, the perovskite optoelectronic device is a perovskite solar cell. A perovskite solar cell may comprise a hole transport layer, an electron transport layer, a perovskite layer between the hole transport layer and the electron transport layer, and the passivating ligands bound to the perovskite layer. As noted above, the passivating ligands may be located at the interface between the perovskite layer and the electron transport layer. Each of these components of the perovskite solar cell, as well as additional components that may be used, are described in further detail below.

The perovskite of the perovskite layer refers to a chemical compound having a perovskite structure such as ABX₃. In embodiments, A is a protonated amine or an alkali metal ion; B is a divalent metal ion; and X is an anion capable of bonding to B. A variety of protonated amines may be used, e.g., a primary ammonium, a secondary ammonium, a tertiary ammonium, a quaternary ammonium, or an iminium. Suitable illustrative protonated amines include, e.g., NH₄⁺ (ammonium); CH₃NH₃⁺ (methylammonium, MA); CH(NH₂)₂⁺ (formamidinium, FA); (CH₃)₂NH₂⁺ (dimethylammonium); (CH₃CH₂)NH₃⁺ (ethylammonium); (NH₂)₃C⁺ (guanidinium); and (CH₃)₄N⁺ (tetramethylammonium). A variety of alkali metal ions may be used, e.g., Cs⁺. A variety of divalent metal ions may be used, e.g., a post-transition metal or a metalloid such as Ge²⁺, Sn²⁺, or Pb²⁺. A variety of anions may be used, e.g., a halide such as F⁻, Cl⁻, Br⁻, or I⁻.

The term “perovskite” (as well as the formula ABX₃) encompasses alloys including more than one type of A in varying relative amounts (provided the sum of the amounts is about 1); more than one type of B in varying relative amounts (provided the sum of the amounts is about 1); more than one type of X in varying relative amounts (provided the sum of the amounts is about 3); and combinations thereof.

In embodiments, the perovskite has formula ABX₃, wherein A is selected from methylammonium, formamidinium, Cs⁺, and a combination thereof; B is selected from Sn²⁺, Pb²⁺, and both; and X is selected from Br⁻, I⁻, and both. Illustrative perovskites are provided in the Example, below, and include normal bandgap perovskites such as Cs_{0.05}MA_{0.05}FA_{0.90}PbI₃; narrow bandgap perovskites such as MA_{0.25}FA_{0.7}Pb_{0.5}Sn_{0.5}I₃; and wide bandgap perovskites such as Cs_{0.2}FA_{0.8}PbI_{1.9}Br_{1.1}.

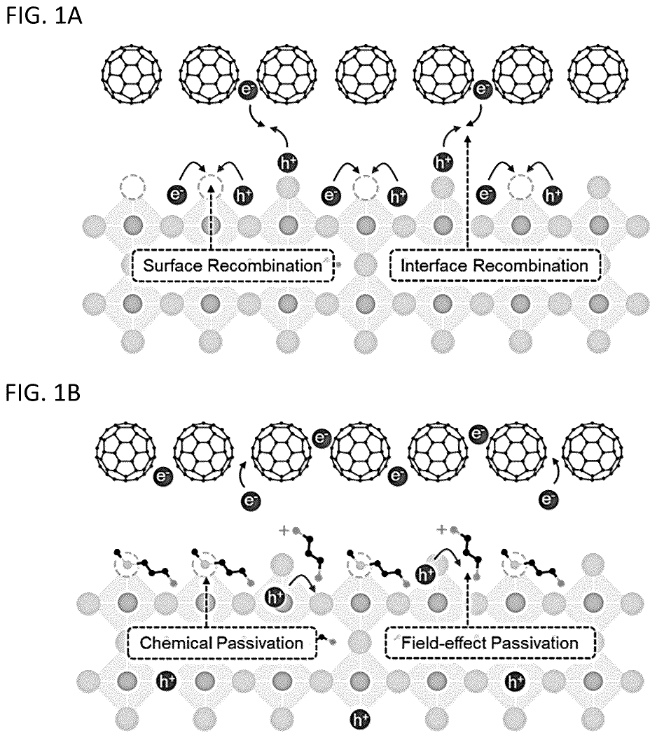

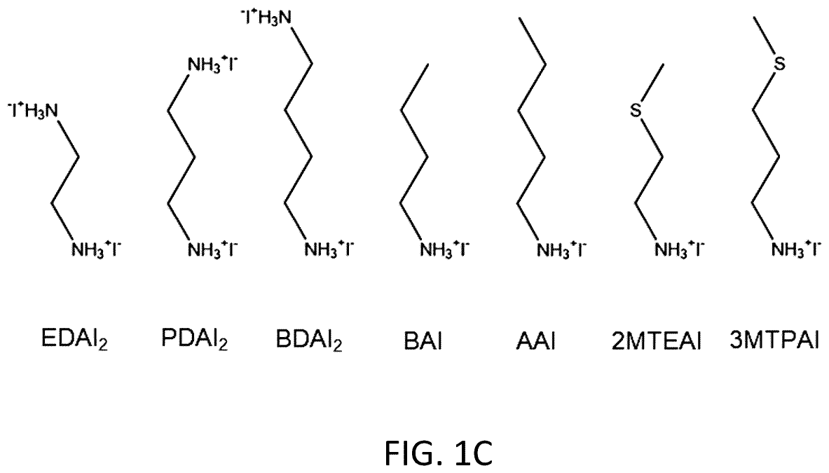

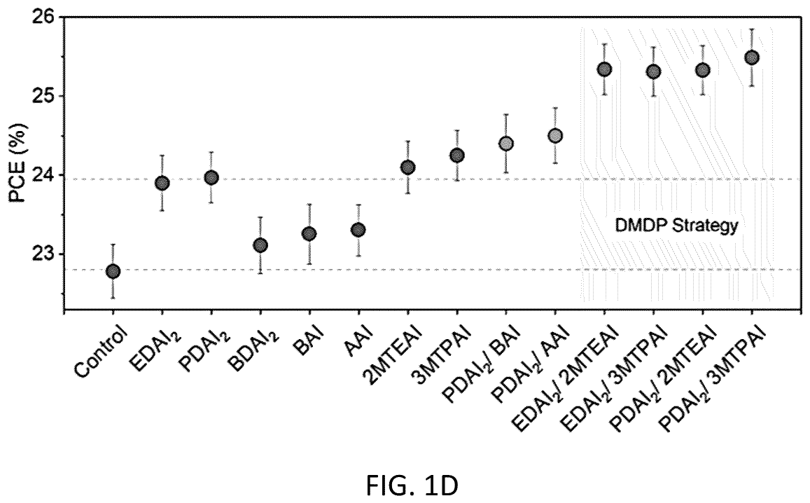

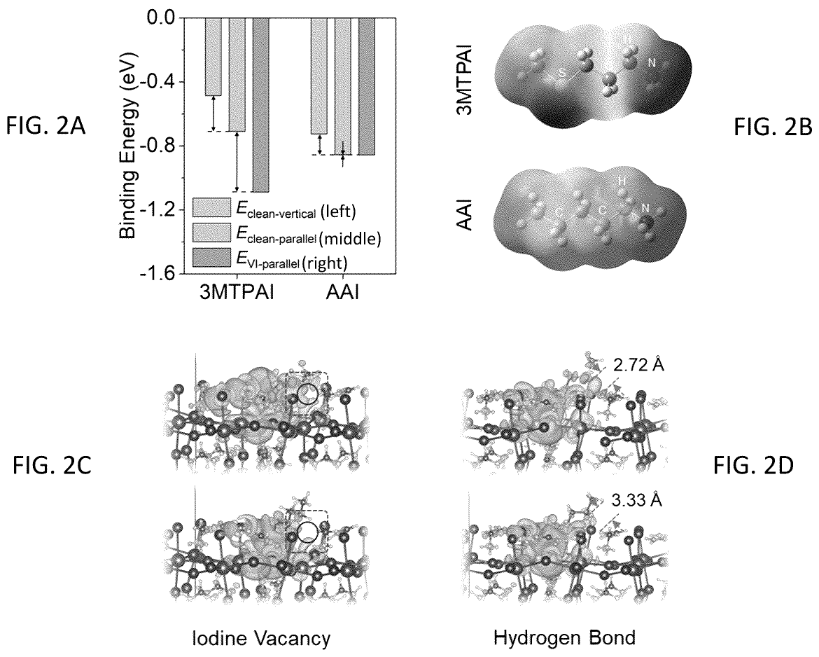

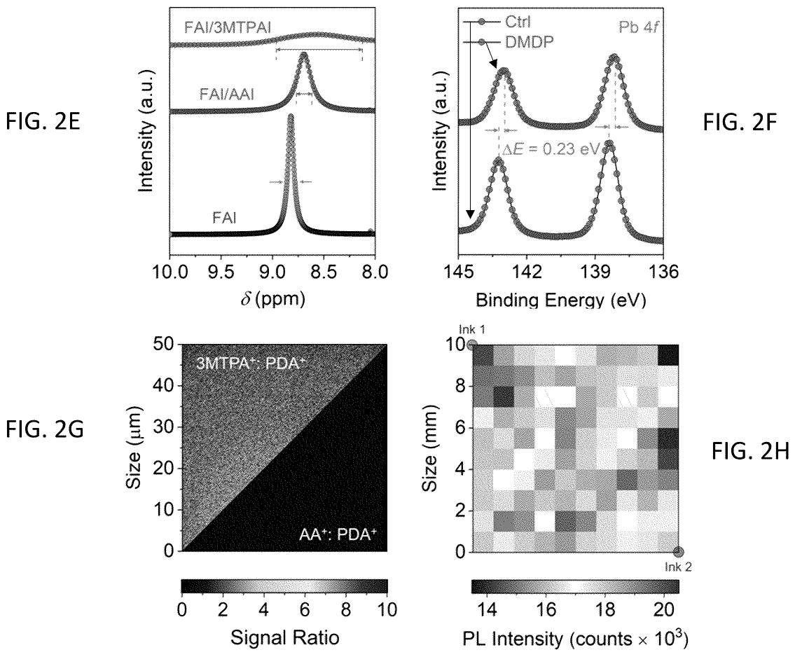

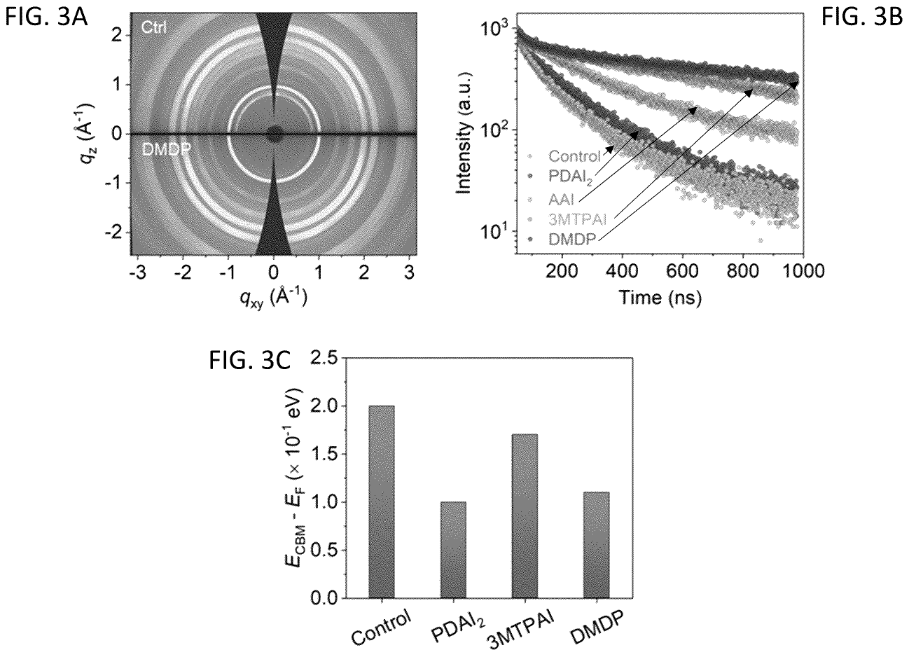

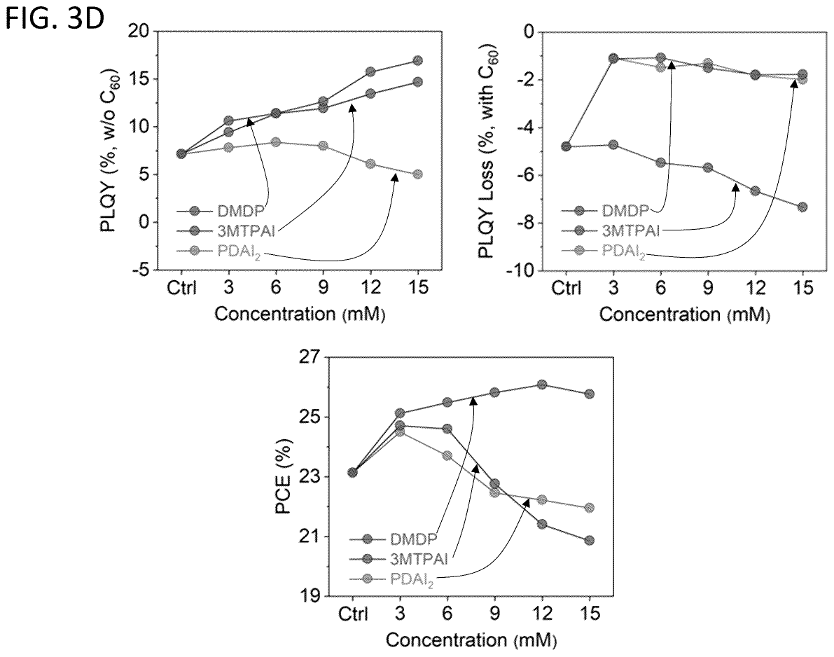

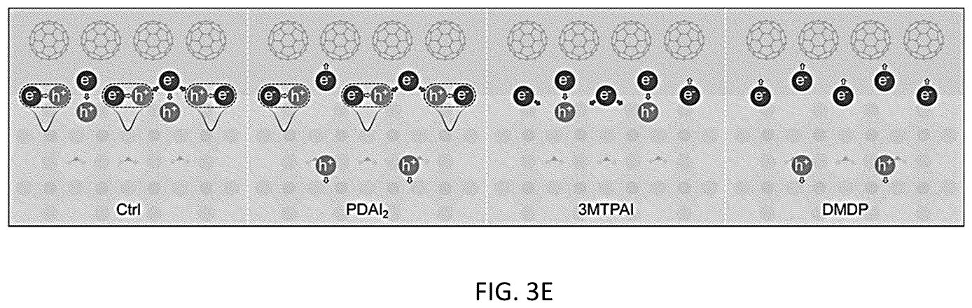

The passivating ligands which bind to the perovskite of the perovskite layer comprise chemical passivating ligands. A chemical passivating ligand is a chemical compound capable of binding to the perovskite and capable of reducing surface recombination, i.e., the non-radiative recombination of electrons and holes, on the perovskite layer. Surface recombination is illustrated in the left portion of FIG. 1A and its inhibition by the chemical passivating ligands illustrated in the left portion of FIG. 1B. As described in the Example, below, time-resolved photoluminescence (TRPL) measurements may be used to confirm that a selected chemical passivating ligand reduces surface recombination as compared to a control perovskite layer free of the chemical passivating ligand. (See FIG. 3B.) Regarding binding, the chemical passivating ligand includes those that are capable of binding (e.g., via coordinative bonding) with two different types of defect sites of the perovskite layer, e.g., an anion vacancy site and a cation vacancy site. Chemical passivating ligands capable of binding both with an uncoordinated cation (e.g., B, the divalent metal ion) and with an uncoordinated anion (i.e., X, the anion) of the perovskite may be used. The chemical passivating ligand may also be capable of non-covalent bonding with the perovskite of the perovskite layer, e.g., hydrogen bonding with a hydrogen-containing cation (e.g., A as a protonated amine) of the perovskite. As described in the Example, below, density functional theory (DFT) calculations, proton nuclear magnetic resonance (¹H NMR) spectroscopy, X-ray photoelectron spectroscopy (XPS), and time-of-flight secondary ion mass spectrometry (ToF-SIMS) may be used to confirm the nature and strength of the binding between a selected chemical passivating ligand and a desired perovskite. (See FIGS. 2A-2G.) As noted above, the binding and suppression of surface recombination by the chemical passivating ligands is schematically illustrated in the left portion of FIG. 1B.

A suitable chemical passivating ligand comprises (or consists of) a linking group, a first perovskite binding group covalently bound to the linking group, and a second perovskite binding group covalently bound to the linking group. The exact chemical composition of the chemical passivating ligand, including these various groups depends upon the desired perovskite. However, the first and second perovskite binding groups are different types of chemical groups from one another. One of the first and second perovskite binding groups may be charged (e.g., positively charged) and the other may be uncharged (neutral). An illustrative linking group is an alkyl group. The alkyl group may be a linear alkyl group having, e.g., from 1 to 8 carbon atoms. This includes having 2, 3, 4, 5, 6, 7, or 8 atoms. The alkyl group may be unsubstituted by which it is meant having no heteroatoms, only carbon and hydrogen atoms. An illustrative first perovskite binding group is a cationic group such as an ammonium group (—NH₃⁺). An illustrative second perovskite binding group is an electron donating group such as a thioether group. The thioether group may be represented by —SR′, wherein R′ is an alkyl group as defined above. In embodiments, R′ is methyl. In both the ammonium group and the thioether group, the “—” represents the covalent bond to the linking group. In embodiments, the chemical passivating ligand is selected from those having formula ⁺H₃N—R—SR′, wherein R and R′ are independently selected alkyl groups as defined above. Illustrative chemical passivating ligands are provided in the Example, below, and include 3-(methylthio)propylammonium and 2-(methylthio)ethylammonium.

The presence of the thioether groups described herein distinguish the present chemical passivating ligands from other types molecules that comprise sulfur but wherein the sulfur is part of a disulfide group (S—S); is bound to hydrogen (SH); is bound to oxygen (e.g., SO₂ or SO₃); is part of a thiocyanate group (SCN); is part of a ring structure (e.g., thiophene); is part of a thiourea group; or is part of a isothiouronium group. That is, these types of molecules comprising sulfur in these ways may be excluded from use.

A single type of chemical passivating ligand or multiple, different types of chemical passivating ligands may be used. Various amounts of the chemical passivating ligand may be used, including to achieve a desired power conversion efficiency (PCE), e.g., a maximum PCE, for a perovskite solar cell containing the chemical passivating ligands. (See FIG. 3D.)

The chemical passivating ligands may be synthesized as described in the Example, below.

According to a dual passivation scheme provided by the present disclosure, the passivating ligands which bind to the perovskite of the perovskite layer may further comprise field-effect passivating ligands in addition to the chemical passivating ligands described above. A field-effect passivating ligand is a chemical compound capable of binding to the perovskite and capable of reducing interfacial recombination, i.e., the non-radiative recombination of electrons and holes, at an interface formed between the perovskite layer and another functional layer, e.g., an electron transport layer. The term “field-effect” is used as the interfacial recombination is reduced by the field-effect passivating ligands inducing a surface dipole to repel minority carriers as well as doping (e.g., n-type doping) at the interface. Interfacial recombination is illustrated in the right portion of FIG. 1A and the binding and suppression of interfacial recombination by the field-effect passivating ligands is schematically illustrated in the right portion of FIG. 1B.

Diammonium compounds, including alkyldiammonium compounds, are suitable field-effect passivating ligands. Alkyldiammonium compounds may be represented by ⁺H₃N—R—NH₃+, wherein R is alkyl. R may be a linear alkyl group having, e.g., from 2 to 8 carbon atoms. This includes having 2, 3, 4, 5, 6, 7, or 8 atoms. The alkyl group may be unsubstituted by which it is meant having no heteroatoms, only carbon and hydrogen atoms. Illustrative field-effect passivating chemical passivating ligands are provided in the Example, below, and include ethane-1,2-diammonium and propane-1,3-diammonium.

A single type of field-effect passivating ligand or multiple, different types of field-effect passivating ligands may be used. Various amounts of the field-effect passivating ligand may be used, including to achieve a desired power conversion efficiency (PCE), e.g., a maximum PCE, for a perovskite solar cell containing the chemical passivating ligands. (See FIG. 3D.) This includes use of a certain concentration ratio of the chemical passivating ligand(s) to the field-effect passivating ligand(s) to achieve this desired PCE, e.g., from 3:1 to 1:3, including 2:1, 1:1, and 1:2.

Description of the chemical and field-effect passivating ligands above encompasses the ionic form thereof as well as the salt form in which a counter ion may be present such as a halide, e.g., I⁻. (See FIG. 1C.)

The chemical and field-effect passivating ligands may be localized to surfaces of the perovskite layer and/or grain boundaries therein. As noted above, this includes being localized at surfaces of the perovskite layer that are in contact with, or form an interface with, other material layers of the perovskite solar cell, e.g., the electron transport layer.

For perovskite solar cells, various materials may be used in the hole transport layer (e.g., carbazole-based self-assembled monolayers (SAMs), poly(3,4-ethylenedioxythiophene) polystyrene sulfonate (PEDOT:PSS)) and the electron transport layer (e.g., buckminsterfullerene, C₆₀, and its derivatives). Any other material layers typically used in perovskite solar cells may be included, e.g., a substrate (e.g., glass, indium tin oxide, fluorine-doped tin oxide), contacts (e.g., various metals), a hole blocking layer (e.g., bathocuproine), an electron blocking layer, etc.

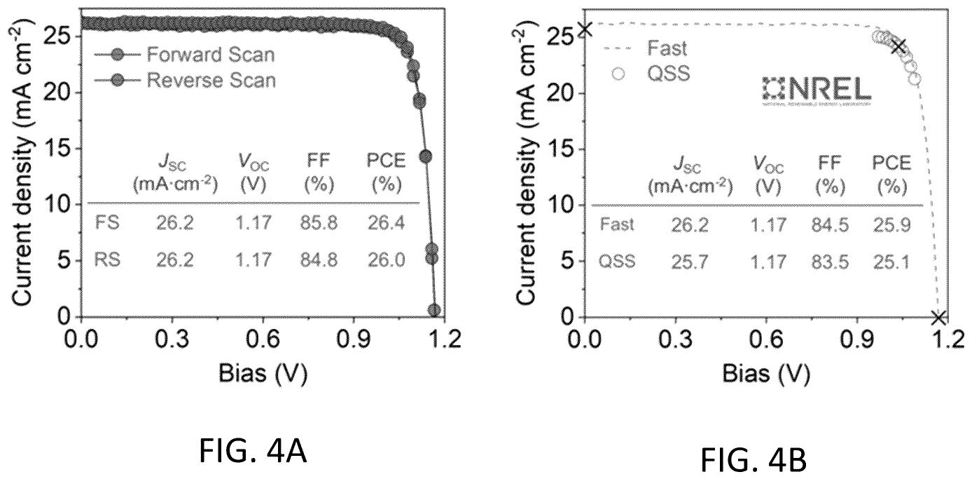

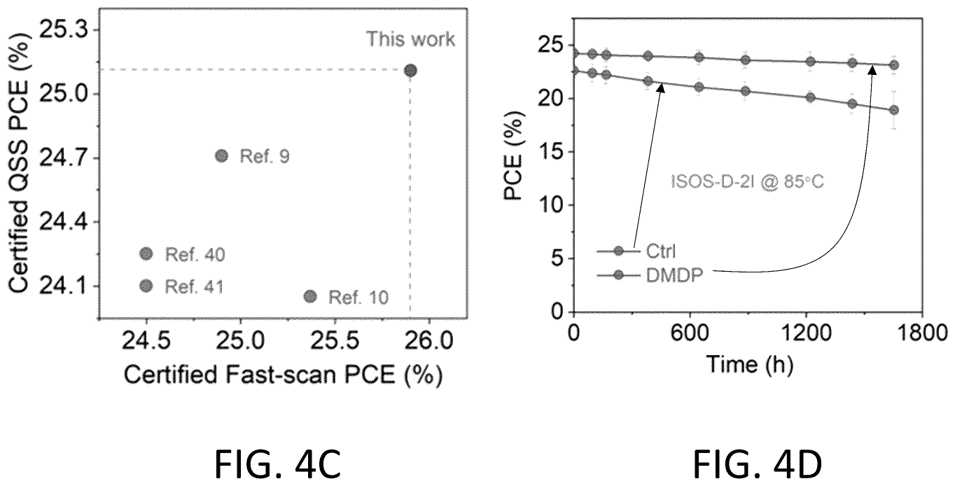

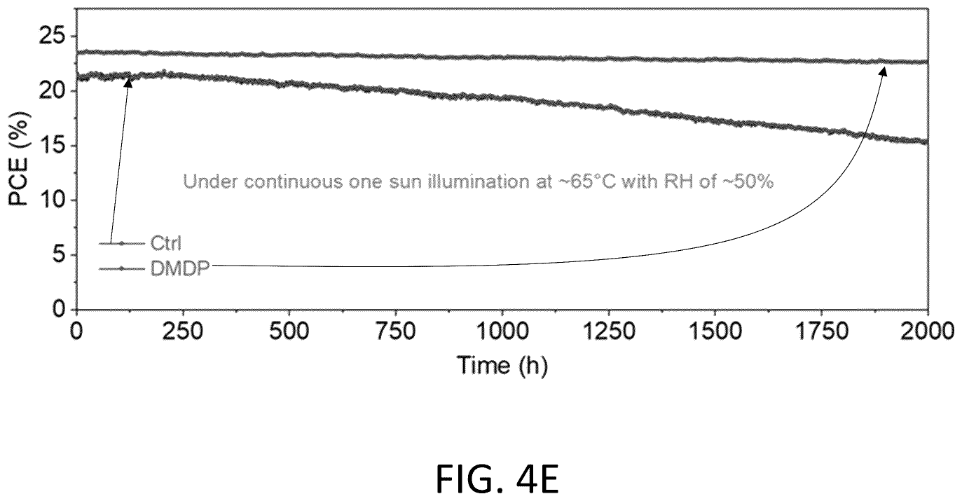

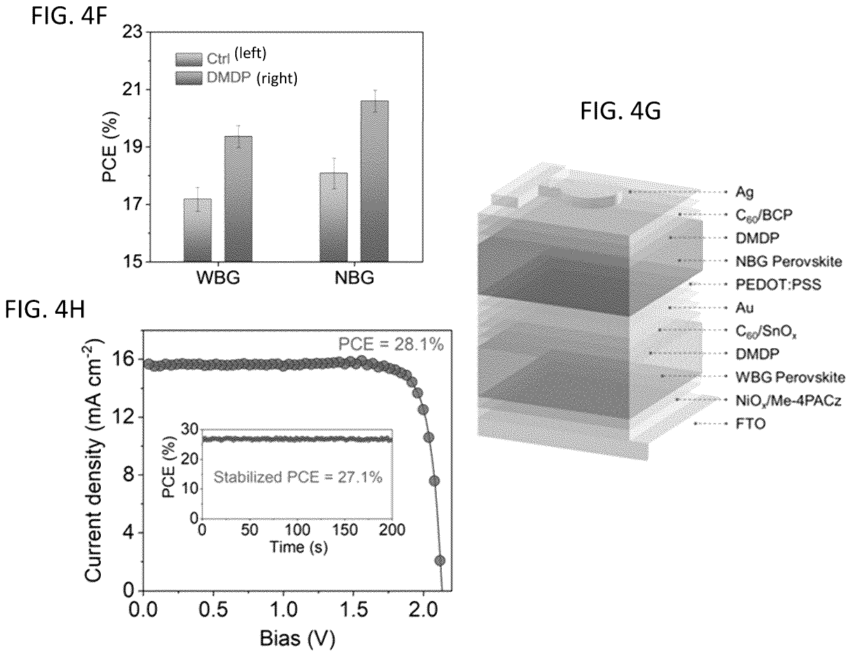

The perovskite solar cells may be configured according to a particular architecture such as an inverted (pin) architecture in which the perovskite solar cell is illuminated through the electron transport layer. The perovskite solar cell may be a single junction or a multijunction device (e.g., a tandem device). An illustrative tandem device is shown in FIG. 4G.

Perovskite solar cells comprising the present chemical passivating ligands, particularly in combination with the field-effect passivating ligands, are characterized by high power conversion efficiencies (PCEs) which may be tested as described in the Example, below. (See FIGS. 1D, 3D, 4C, and 4F.) In addition, as shown in FIG. 4H, an illustrative perovskite solar cell achieved a PCE of over 28%. Thus, the present perovskite solar cells may be characterized as exhibiting a PCE of at least 25%, at least 26%, at least 27%, at least 28%, at least 29%, at least 30%, or a range of between any of these values. These values may refer to the conditions used during testing as described in the Example, below.

Various methods may be used to fabricate the present perovskite optoelectronic devices and achieve passivation of perovskite layers. However, in embodiments, a solution comprising any of the disclosed passivating ligands at a desired concentration (e.g., from 2 to 10 mM, from 3 to 9 mM, or from 3 to 6 mM) and a solvent is deposited (e.g., via spin coating) onto any of the disclosed perovskite layers, followed by annealing.

Methods of using the present perovskite optoelectronic devices are also provided. The methods comprise illuminating any of the disclosed perovskite optoelectronic devices with light to generate charge carriers, and collecting the charge carriers.

The chemical passivating ligands themselves are also encompassed by the present disclosure, including compositions comprising the chemical passivating ligands. For example, in embodiments, a composition is provided which comprises any of the disclosed chemical passivating ligands and any of the disclosed perovskites, which may be in the form of a layer. The disclosed field-effect passivating ligands may also be included in such compositions.

### Example

### Materials and Methods

### Materials

[4-(3,6-Dimethyl-9H-carbazol-9-yl)butyl]phosphonic Acid (Me-4PACz), PbI₂ (99.99%), PbBr₂ (99.99%), and PbCl₂ (99.99%) were purchased from TCI America™. C₆₀, bathocuproine (BCP), and methylammonium chloride (MACl) were purchased from Xi'an Polymer Light Technology. CsI (99.99%), SnI₂ (99.999%), Sn powder (99.99%), SnF₂ (99%), guanidinium thiocyanate (GuaSCN, 99%), ethane-1,2-diammonium iodide (EDAI₂, 98%), 2-(methylthio)ethylamine (2MTEA, 97%), amylamine (AA, 99%), n-Butylammonium iodide (BAI, 98%), 1,4-diaminobutane (BDA, 99%), and 3-(methylthio)propylamine (3MTPA, 97%) were purchased from Sigma-Aldrich. Poly(3,4-ethylenedioxythiophene) polystyrene sulfonate (PEDOT:PSS, Al 4083) was purchased from Ossila. 3-(methylthio)propylamine hydroiodide (3MTPAI), 2-(methylthio)ethylamine hydroiodide (2MTEAI), amylamine hydroiodide (AAI), and 1,4-diaminobutane dihydroiodide (BDAI₂) were obtained by the reaction of hydroiodic acid and 3MTPA/2MTEA/AA/BDA with molar ratios of 1:1/1:1/1:1/2:1, respectively: hydroiodic acid was slowly added to amines under stirring in the ice water bath. The solution was stirred in the ice water for 2 hours, followed by rotary evaporation at 50° C. until the white solid was obtained, which was washed with diethyl ether several times. Finally, the product was dried in a vacuum drying oven to obtain the corresponding ammonium halide salts. Formamidinium iodide (FAI), methylammonium iodide (MAI), and propane-1,3-diammonium iodide (PDAI₂) were purchased from Greatcell Solar Materials. N, N-dimethylformamide (DMF, anhydrous, 99.8%), dimethyl sulfoxide (DMSO, anhydrous, 99.9%), isopropanol (anhydrous, 99.5%), ethanol (anhydrous, 99.5%), chlorobenzene (anhydrous, 99.8%), toluene (anhydrous, 99.8%), and anisole (anhydrous, 99.7%) were purchased from the Millipore Sigma. All the materials were used as received without any purification.

### Perovskite Precursor Solutions

Normal bandgap perovskite. Cs_{0.05}MA_{0.05}FA_{0.90}PbI₃ perovskite precursors were dissolved with 5 mol % MAPbCl₃ in a mixed DMF and DMSO solvent (4:1 v/v) at a concentration of 1.6 M.

Narrow bandgap (NBG) perovskite. 1.8 M Cs_{0.05}MA_{0.25}FA_{0.7}Pb_{0.5}Sn_{0.5}I₃ perovskite precursors were dissolved in a mixed DMF and DMSO solvent (3:1 v/v) with the addition of 2 mol % Sn power, 5 mol % SnF₂ and 2 mol % GuaSCN.

Wide bandgap (WBG) perovskite. 1.1 M Cs_{0.2}FA_{0.8}PbI_{1.9}Br_{1.1} precursors were prepared in mixed solvents of DMF and DMSO (4:1 v/v). All the perovskite solutions were stirred at room temperature for 30 min.

### Solar Cell Fabrication

Single-junction normal bandgap PSCs. Fluorine-doped tin oxide (FTO) glasses were cleaned using detergent, deionized water, acetone, and isopropanol, each for 15 min in an ultrasonic bath, followed by ultraviolet ozone treatment for 30 min. The hole transport layer (HTL) was NiOₓ/4PACz. NiOₓ was synthesized as described in H. Chen et al., Nat. Photonics 16, 352-358 (2022). The NiOₓ solution (5 mg/mL in deionized water and isopropanol (3:1 v/v)) was spin-coated on the substrates at 3,000 r.p.m. for 30 s. Then, a 0.5 mg/mL 4PACz in ethanol solution was spin-coated on NiOₓ at 4,000 r.p.m. for 30 s, followed by annealing at 100° C. for 10 min. The perovskite film with a thickness of ˜600 nm deposition was done in the N₂ glovebox with O₂ and H₂O content less than 1 ppm. The perovskite solution was filtered by a 0.22 μm polytetrafluoroethylene (PTFE) membrane and spin-coated at 1000 r.p.m for 10 s (acceleration rate 200 r.p.m./s) and 5000 r.p.m. for 30 s (acceleration rate 2000 r.p.m./s), respectively. At the 20 second mark of the second step, 300 L anisole was dropped as the antisolvent. The films were then annealed at 100° C. for 15 min. For the mono-molecular passivation treatment, 100 μL 3 mM PDAI₂ or EDAI₂ or BDAI₂ isopropanol/chlorobenzene (1:1 v/v) solution was deposited on the perovskite films by dynamic spinning-coating at 4500 r.p.m for 25 s, followed by annealing at 100° C. for 5 min. For the bi-molecular passivation, 12 mM 3MTPAI or AAI or 2MTEAI or BAI and 6 mM PDAI₂ or EDAI₂ was dissolved in the isopropanol/chlorobenzene (1:1 v/v) solvent and then 100 μL mixed solution was filtered and dynamically spin-coated on the perovskite films at 4500 r.p.m for 20 s, followed by annealing at 100° C. for 5 min. For the electron transport layer (ETL), 30 nm C₆₀ was thermally evaporated on the perovskite films under a high vacuum of ˜10⁷ Torr, followed by 7 nm BCP evaporation as a hole-blocking layer. Finally, 140 nm Ag electrode was evaporated under a high vacuum of ˜10⁻⁷ Torr.

Single-junction WBG PSCs. The NiOₓ/4PACz HTL deposition was the same as described above. WBG perovskite solution was filtered by a 0.22 μm PTFE membrane and spin-coated at 4500 r.p.m for 30 s (acceleration rate 2000 r.p.m./s). 300 μL anisole was dropped at the last 10 s. The films were annealed at 100° C. for 15 min. For the diammonium-methylthio dual passivation (DMDP) devices, 12 mM 3MTPAI and 6 mM PDAI₂ were dissolved in an isopropanol/chlorobenzene (1:1 v/v) solvent and then 100 μL mixed solution was filtered and dynamically spin-coated on the perovskite films at 4500 r.p.m for 20 s, followed by annealing at 100° C. for 5 min. The C₆₀, BCP, and Ag deposition were the same as normal bandgap devices.

Single-junction NBG PSCs. The PEDOT:PSS was diluted to ⅓ of its original concentration using isopropanol and filtered with a 0.45 μm PTFE membrane. The 50 nm PEDOT:PSS layer was deposited by a spin-coating method at 5000 r.p.m. for 30 s, followed by annealing at 150° C. for 20 min in the ambient. The NBG perovskite solution was filtered by a 0.22 μm PTFE membrane and spin-coated at 1000 r.p.m for 10 s (acceleration rate 500 r.p.m./s) and 3000 r.p.m. for 45 s (acceleration rate 1500 r.p.m./s), respectively. 300 μL chlorobenzene was dropped at the last 18 s, followed by annealing at 100° C. for 10 min. For the DMDP devices, 3 mM 3MTPAI and 3 mM EDAI₂ was dissolved in an isopropanol/toluene (1:1 v/v) solvent and then 100 μL mixed solution was filtered and dynamically spin-coated on the perovskite films at 4500 r.p.m for 20 s, followed by annealing at 100° C. for 5 min. The C₆₀, BCP, and Ag deposition were the same as described in the normal bandgap PSCs.

Tandem devices. A WBG subcell was first fabricated: the NiOₓ/4PACz HTL deposition was the same as described above. The WBG perovskite solution was spin-coated at 4500 r.p.m for 30 s and 300 μL anisole was dropped at the last 10 s. The 500 nm films were obtained after annealing at 100° C. for 15 min. 12 mM 3MTPAI and 6 mM PDAI₂ were dissolved in an isopropanol/chlorobenzene (1:1 v/v) solvent and then 100 μL mixed solution was filtered and dynamically spin-coated on the perovskite films at 4500 r.p.m for 20 s, followed by annealing at 100° C. for 5 min. The C₆₀ deposition was the same as normal bandgap devices. A 20 nm SnO₂ was deposited by atomic layer deposition, and 1 nm Au was deposited by thermal evaporation. The NBG subcell was then fabricated: the diluted PEDOT:PSS solution was spin-coated at 5000 r.p.m. for 30 s, followed by annealing at 150° C. for 20 min in the ambient air. The NBG perovskite solution was spin-coated at 1000 r.p.m for 10 s (acceleration rate 500 r.p.m./s) and 3000 r.p.m. for 45 s (acceleration rate 1500 r.p.m./s), respectively. 300 μL chlorobenzene was dropped at the last 18 s, followed by annealing at 100° C. for 10 min, and a 1-μm-thick film was obtained. 3 mM 3MTPAI and 3 mM EDAI₂ were dissolved in an isopropanol/toluene (1:1 v/v) solvent and then 100 μL mixed solution was filtered and dynamically spin-coated on the perovskite films at 4500 r.p.m for 20 s, followed by annealing at 100° C. for 5 min. 30 nm C₆₀, 7 nm BCP, and 140 nm Ag electrode were thermally evaporated to complete the tandem devices.

### Characterizations

Current-density-voltage (J-V) characteristics. The J-V characteristics were measured in a nitrogen glovebox at room temperature using a Keithley 2401 digital source-meter under simulated AM 1.5 G irradiation from a Xe arc lamp (Sciencetech Al Light Line Class AAA solar simulator). The light intensity was calibrated by a Sciencetech SCI-REF-Q silicon cell from before measurement, and no preconditioning was applied. The scanning step was 20 mV with a scanning rate of 70 mV/s. The active area of the solar cells was defined by an opaque metal mask with an aperture area of 0.049 cm².

Stability test. The operational stability tests at elevated temperatures were conducted by putting the encapsulated devices in the air with relative humidity of ˜50% under 1-sun illumination (Sunbrick G2V) at 65° C. which was monitored by an infrared thermometer. For thermal stability tests, the encapsulated cells were heated at 85° C. in nitrogen. The device performance was evaluated periodically. Encapsulation was performed using a capping glass slide, with ultraviolet-adhesive (Lumtec LT-U001) as a sealant.

Crystallographic characterizations. X-Ray diffraction (XRD) was carried out by a Rigaku Miniflex diffractometer (Cu Kai radiation). Grazing-incidence wide-angle X-ray Scattering (GIWAXS) was conducted on perovskite films at the Brockhouse X-ray Diffraction and Scattering Sector Low Energy Wiggler (BXDS-WLE) beamline of the Canadian Light Source (CLS) using a photon energy of 15.12 keV (λ=0.82 Å). A Rayonix MX300 detector 328.04 mm away from the sample was used for collecting patterns.

Other characterizations. Time of flight secondary ion mass spectrometry (ToF-SIMS) was collected by an IONTOF M6 instrument using a primary 30 keV Bi ion source with an analysis area of 50×50 μm². SEM images were collected by a JEOL JSM-7900FLV microscope using a 5 keV and 10 keV electron beam for surface and cross-section images, respectively. Photoluminescence (PL) maps were collected using a confocal Raman system (excitation wavelength=633 nm) integrated with SWIFT and DuoScan technologies. A time-resolved photoluminescence (TRPL) measurement was conducted using an Edinburgh FS5 spectrofluorometer with a 373 nm excitation laser. The luminescence quantum yield was measured by a LuQY Pro System (Quantum Yield Berlin) under the excitation of a 532 nm laser (100 mW). X-ray photoelectron spectroscopy (XPS) and ultraviolet photoelectron spectroscopy (UPS) were performed on a Thermo Scientific ESCALAB 250Xi with an X-ray spot size of 500 μm. Contact potential difference and photocurrent were obtained by a Bruker Photocurrent and Thermal AFM (Pt/Ir-coated cantilevers), with a scan rate of 0.25 Hz and scan area of 5×5 μm². Nuclear magnetic resonance spectroscopy (NMR) was performed using a Bruker Avance HD 500 MHz w/Prodigy probe (×500) on solutions prepared by dissolving FAI, a 1:1 molar ratio mixture of FAI and 3MTPAI, as well as a 1:1 molar ratio mixture of FAI and 3MTPAI powder, in a DMSO-d6 solvent at a concentration of 0.12 M. The transient absorption (TA) spectra were measured with a spectrometer (Acton SP2300, Princeton Instruments). Femtosecond laser pulses of 800 nm were generated by a Ti:Sapphire laser at a 250 kHz repetition rate (Mira, Coherent), which were then amplified by a Ti:Sapphire amplifier (RegA, Coherent). The pulses were passed through an optical parametric amplifier (OPA 9400, Coherent) to select 500 nm light as the pump pulse. The probe pulses were generated by focusing the initial 800 nm pulse into a sapphire crystal, which resulted in a white light. EQE measurements were performed without bias voltage in ambient air using a QuantX-300 Quantum Efficiency Measurement System (Newport) and bias illumination from bright LEDs, with emission peaks of 850 and 450 nm used for measurement of the front and back subcells, respectively.

### Computation

First-principles calculations based on density functional theory (DFT) were carried out using the Vienna Ab initio Simulation Package (VASP). The generalized gradient approximation (GGA) of the Perdew-Burke-Ernzerhof (PBE) functional was employed as the exchange-correlation functional. The DFT-D3 method for the van der Waals (vdW) correction was included. The plane-wave cutoff energy was 400 eV. The energy and force convergence criteria were set to 10⁵ eV and 0.02 eV·Å-1, respectively. The binding energies (E_{b}) of ligands with the perovskite surface were calculated as E(ligand@perovskite)-E(ligand)-E(perovskite), where E(structure) is the total energy of the corresponding structures. The electrostatic potentials of the ligands were calculated in the Gaussian 09 package at the B3LYP/def2TZVP level with DFT-D3. The plots of the electrostatic potentials were obtained with the help of Multiwfn code.

### Results and Discussion

### Exploring Class 1 and 2 Molecule Combinations

The inventors sought to address complex interface carrier recombination issues using a combination of different molecules, each with distinct functionalities. The first class of molecules that were incorporated repelled hole carriers to reduce interface recombination through field-effect passivation (FIG. 1B, right portion). The second class of molecules interacted with defect sites to form chemical bonds to reduce surface recombination through chemical passivation. (FIG. 1B, left portion).

Diammonium ligands, in which one —NH₃⁺ group anchors to the perovskite surface and the other extends away from it, can induce a surface dipole and n-type doping and provide effective field-effect passivation for both narrow bandgap (NBG) (˜1.2 eV) and wide bandgap (WBG) (˜1.8 eV) PSCs. The passivation effect of different diammonium ligands on normal bandgap (˜1.5 eV) PSC devices was explored. The device architecture consisted of fluorine-doped tin oxide (FTO)/NiOₓ/[4-(3,6-dimethyl-9H-carbazol-9-yl)butyl]phosphonic acid (Me-4PACz)/perovskite/passivation layer/C₆₀/Bathocuproine (BCP)/Ag (cross-section SEM images were obtained, data not shown). Optical constants of materials were also obtained (data not shown). The current-voltage characteristics showed that ethane-1,2-diammonium (EDAI₂) and propane-1,3-diammonium iodide (PDAI₂) exhibit high binding energy to the perovskite surface (data not shown). This enables a device performance improvement compared with the control devices (without passivation), from PCEs of ˜22.8% to ˜23.9% with active areas of 0.05 cm² (FIG. 1D). Thus, diammonium ligands work well in normal bandgap PSCs, and the PCE improvement may be attributed to field-effect passivation that repels minority carriers.

A second molecule was then sought in order to add a chemical passivation function. n-butylammonium iodide (BAI) was first examined in combination with PDAI₂. Its addition increased PCE to ˜24.3% compared with PDAI₂-only. Extending the chain length to amylamine hydroiodide (AAI) further improved the average efficiency to ˜24.5%.

The electrical dipole moment was then further tuned by incorporating sulfur as a donor atom in the alkyl chain by synthesizing methylthio-based ammonium ligands. Two compounds were explored, including 2-(methylthio)ethylamine hydroiodide (2MTEAI) and 3-(methylthio)propylamine hydroiodide (3MTPAI). The use of both types of molecules (diammonium molecules and methylthio molecules) led to improved PCE across several combinations, namely EDAI₂/2MTEAI, PDAI₂/2MTEAI, EDAI₂/3MTPAI, and PDAI₂/3MTPAI, in comparison to both the control device and single-molecule passivated devices. The highest average PCE (>25.5%) was achieved with PDAI₂/3MTPAI (FIG. 1D). The PDAI₂/3MTPAI combination was evaluated for further investigation.

### PDAI₂/3MTPAI Characteristics

Density function theory (DFT) was used to compare 3MTPA⁺ versus AA⁺ by modeling ligand orientations of 3MTPA and AA on the perovskite surface (data not shown). The binding energy difference (ΔE_{clean}) between the parallel (E_{clean-parallel}) and vertical configurations (E_{clean-vertical}) was used as a measure of ligand orientation. A larger ΔE_{clean} value of −0.22 eV for 3MTPA indicated a stronger preference for the parallel orientation as compared to −0.13 eV for AA (FIG. 2A). This difference corresponded to greater occupation on the vacancy defect position. Electrostatic potentials in the ligands (FIG. 2B) showed that 3MTPA, when compared to AA, had a lower minimum electrostatic potential (φₘᵢₙ) because of its electron-rich center surrounding the S atom that facilitated binding with the positively charged iodide vacancy. The higher maximum electrostatic potential (φₘₐₓ) at the —NH₃⁺ side also added increased binding strength between the ligand and the surface cation vacancy site of the perovskite.

The passivation effect of the ligands was further evaluated by considering the presence of iodide vacancies, which are the predominant defects on the perovskite surface (atomic structures not shown). The binding energy difference (ΔEᵣₑₗₐₜᵢᵥₑ) between that of the defective surface (E_{VI-parallel}) and the clean surface (E_{clean-parallel}) was evaluated. ΔEᵣₑₗₐₜᵢᵥₑ of AA with the perovskite remained nearly unchanged, regardless of the presence or absence of iodide vacancy. In contrast, ΔEᵣₑₗₐₜᵢᵥₑ=−0.38 eV was obtained for 3MTPA, indicating a favorable interaction with the defective sites. 3MTPA induced a notable charge redistribution that accumulated charges at the iodide vacancy, assigned to S—Pb coordination bonding (FIG. 2C).

Charge transfer between 3MTPA and formamidinium (FA) was also observed (FIG. 2D), accompanied by a shorter distance of 2.72 Å between the sulfur atom in 3MTPA and the hydrogen atom in FA that indicated the formation of a hydrogen bond. In contrast, the distance between the carbon atom at the corresponding site in AA and the hydrogen atom in FA was 3.33 Å. Thus, the formation energy of the FA vacancy increased from −0.79 eV to −0.71 eV (data not shown). ¹H nuclear magnetic resonance (¹H NMR) spectra showed that the amino proton peak of FAI at δ=8.82 parts per million (ppm) exhibited increased broadening and shifted to a lower field after mixing with 3MTPAI compared to AAI (FIG. 2E). These changes again indicated stronger hydrogen bonding interactions between 3MTPA and FA than that with AA. The computation work suggested that the methylthio group provided stronger binding compared with ligands that relied on ammonium functional groups alone.

Diammonium-methylthio dual passivation (DMDP) was assessed using x-ray photoelectron spectroscopy (XPS). The Pb 4f peaks of the passivated perovskite film shifted toward lower binding energy of 0.23 eV compared to the control film (FIG. 2F), which was attributed to an increased electron density at Pb²⁺. Time-of-flight secondary ion mass spectrometry (ToF-SIMS) was employed to analyze the surface ligand distribution. Comparing signal ratios of PDA:3MTPA and PDA:AA under identical conditions on perovskite films with PDAI₂/3MTPAI and PDAI₂/AAI bimolecular passivation, it was found that the signal ratio of 1:2.7 for PDA:3MTPA was lower than the ratio of 1:1.1 for AA:PDA (FIG. 2G). This suggests that 3MTPA had a stronger binding affinity to the perovskite surface and better a passivation effect of defects, consistent with its higher binding energy (binding energy data not shown).

FIG. 2H illustrates the centimeter-scale photoluminescence (PL) intensity distribution of a perovskite film with Gaussian-distributed passivators on the surface (dual-spray inking approach not shown). The region surrounding the PDAI₂/3MTPAI center exhibited a higher PL emission than the corresponding region for PDAI₂/AAI, and the contour region with the lowest PL intensity was skewed toward the PDAI₂/AAI center.

Scanning electron microscopy (SEM) images revealed dense polygonal grains with sizes of ˜500 nm for the control perovskite film; the morphologies were unchanged after DMDP passivation (data not shown). Grazing-incidence wide-angle x-ray scattering (GIWAXS) did not reveal any peaks at low scattering vectors q in the DMDP-based film, which indicated that no low-dimensional perovskite formed (FIG. 3A). The peak at ˜0.84 Å⁻¹ in the control sample was ascribed to the presence of δ-FAPbI₃ formed in the ambient humid air during the measurement. The suppression of δ-FAPbI₃ in the DMDP-based film indicated improved ambient stability. The unchanged surface dimensionality was further corroborated by transient absorption spectra where the passivated film displayed a single bleach spectral feature from the three-dimensional perovskite (data not shown).

To examine the chemical passivation effect of the DMDP strategy on film optoelectronic properties, time-resolved photoluminescence (TRPL) measurements (FIG. 3B and other data not shown) were conducted. Control perovskite films showed a sharp decrease in emission, characteristic of high levels of nonradiative carrier recombination on the bare perovskite surface. Treatment with PDAI₂ showed little improvement in lifetime, reflecting its limited suppression of defect-induced surface recombination. In contrast, the perovskite film treated with 3MTPAI displayed a sustained plateau in the decay curve, reflecting increased carrier lifetime. Without wishing to be bound to any particular theory, this might be due to a combined effect of reduced non-radiative traps and enhanced photon recycling. The re-emission of photons from the WBG subcell might serve to augment photon absorption of the adjacent NBG subcell when it is integrated in the tandem configuration.

Ultraviolet photoelectron spectroscopy (UPS) was used to characterize band edge energies (FIG. 3C and other data not shown). PDAI₂ treatment reduced the energy level difference between the conduction band minimum (E_{CBM}) and the Fermi level (E_{F}) of the perovskite surface to 0.10 eV, compared to 0.20 eV and 0.17 eV for the control and 3MTPAI treatments, respectively. The stronger n-type doping effect of PDAI₂ was attributed to the additional —NH₃⁺ group extending away from the perovskite matrix that induced a surface dipole that repelled the minority carrier at the interface. This treatment enabled field-effect passivation and reduced interface recombination (schematic not shown). This passivation effect was expected to be retained upon the incorporation of 3MTPAI because n-type doping was also observed compared with use of single 3MTPAI.

### Photovoltaic Performance

PDAI₂ did not enhance the PL quantum yield (PLQY) (FIG. 3D) of the perovskite film before C₆₀ deposition and there was little PLQY loss after coating with C₆₀, which were consistent with its field-effect-passivation role. Increased PDAI₂ concentration led to a decrease in both PLQY and PCE, which was attributed to increased surface recombination. For 3MTPAI, in the absence of C₆₀, PLQY increased as 3MTPAI processing solution concentration increased from 3 mM to 15 mM. Upon contact with C₆₀, noticeable PLQY and PCE losses were seen, and these losses became more pronounced at higher concentrations, indicating increased interface recombination. The DMDP strategy improved PLQY of the perovskite/C₆₀ samples and increased the PCE to >26% even at 12 mM concentration of 3MTPAI. In sum, 3MTPAI and PDAI₂ improved passivation and decreased carrier recombination without interfering with one another (FIG. 3E).

The photovoltaic parameters of devices with different treatments at the optimized concentration were obtained (data not shown). The DMDP-based devices showed an improved PCE from 22.8±0.4 to 25.5±0.3% compared to the control device, accompanied by enhancements in open-circuit voltage (V_{OC}) from 1.12±0.01 to 1.16±0.01 V and fill factor (FF) from 78.5±1.3 to 83.8±1.3%. The diode characteristics of the devices in the absence of light showed that the devices in which the DMDP strategy was used presented an average dark saturation current (J₀) reduction by two orders of magnitude compared to the control devices, demonstrating effective inhibition of carrier recombination (data not shown). FIG. 4A shows the current density-voltage (J-V) curves for the champion DMDP device, which exhibited a PCE of 26.4%, with a short-circuit current (J_{SC}) of 26.2 mA cm⁻², V_{OC} of 1.17 V, and FF of 85.8%.

QSS measurement in certification was focused on: here, the highest performance based on maximum power point tracking (MPPT) was a PCE of 25.5% for 100 s (data not shown). A National Renewable Energy Lab (NREL) certification that used the asymptotic maximum power scan protocol (FIG. 4B and other data not shown) reported a QSS PCE of 25.1% for an illuminated area of 0.05 cm² along with a fast-scan PCE of 25.9%, compared to other reported certified QSS PCEs that did not exceed 25% (FIG. 4C and other data not shown). Ref 9: W. Peng et al., Science 379, 683-690 (2023); Ref. 10: Q. Jiang et al., Nature 611, 278-283 (2022); Ref 40: X. Wu et al., Adv. Mater. 35, 2208431 (2023); Ref 41: F. Li et al., Nat. Photonics 17, 478-484 (2023). 1.5 cm² devices were also fabricated using the DMDP treatment which delivered a PCE of 24.0% (data not shown), consistent with increased film homogeneity and reduced localized non-radiative recombination (data not shown).

### Longevity Studies

In the studies of the thermal stability of encapsulated devices, it was found that after 1,600 hours of thermal aging at 85° C. in nitrogen (ISOS-D-2), the DMDP-based devices retained 95% of initial PCE, surpassing the retention of 84% for the control device (FIG. 4D and other data not shown). The operating stability under MPPT under 1 sun of an encapsulated device operating in ambient air was investigated. After 2,000 hours of continuous operation under 1 sun illumination at 65° C. (ISOS-L-3 protocol, where ISOS is the International Summit on Organic PV stability), the DMDP-based device maintained 96% of original PCE, whereas the control device was reduced to 70% of initial PCE (FIG. 4E and other data not shown). A comparison with other PSCs tested using the ISOS-L-3 protocol was collected (information not shown).

### DISCUSSION

To investigate the applicability of the DMDP strategy on other perovskite compositions, PSCs were fabricated with both WBG and NBG perovskite materials. Notably, the average PCE was improved by 14% and 13% when the DMDP strategy was used for NBG and WBG PSCs (FIG. 4F), respectively. The DMDP strategy was applied to monolithic all-perovskite tandem solar cells with the structure of FTO/NiOₓ/Me-4PACz/WBG perovskite/C₆₀/SnOₓ/Au/poly(3,4-ethylenedioxythiophene) polystyrene sulfonate (PEDOT:PSS)/NBG perovskite/C₆₀/SnOₓ/Ag (FIG. 4G). The J-V characteristics of the champion tandem device (FIG. 4H) with an illuminated area of 0.05 cm² exhibited a PCE of 28.1% with a V_{OC} of 2.14 V, J_{SC} of 15.6 mA cm⁻², and FF of 84.0%, and a stabilized PCE of 27.1% under MPPT. A well-matched current response was seen in the external quantum efficiency (EQE) spectra (data not shown).

Realizing both chemical and field-effect passivation by the combined use of methylthio and diammonium molecules has mitigated complex carrier recombination issues at the perovskite/ETL interface. The multi-molecule passivation approach, along with diverse functionalities, is a next-generation passivation strategy that achieves improved performance and stability in perovskite optoelectronics.

Finally, although some sulfur-based passivants have been considered, they have been shown to be unstable and/or excessively reactive. Nevertheless, as described in this Example, molecular screening and theoretical analyses were carried out to compare a different class of sulfur-based molecules, a series of sulfur-functionalized ammonium molecules with varied chain lengths and binding motifs. From these results, the methylthio group (—S—CH₃) emerged as an optimal functionality—strong enough to form S—Pb coordination for defect healing, yet mild enough to preserve lattice integrity. The combined DFT, XPS, and NMR analyses described herein confirmed that this ligand induces charge redistribution at iodide vacancies and establishes stable S—Pb coordination and N—H . . . I hydrogen bonding, leading to a chemically robust and electronically favorable interface. The possibility of achieving this balanced interaction was not predictable from existing sulfur-based studies, but rather was revealed only after extensive iterative experimental and computational research.

Moreover, with regards to 3MTPAI and PDAI₂, in particular, the dual-molecule strategy using these molecules yielded an unexpected nonlinear performance enhancement—a fivefold increase in carrier lifetime, a one-third reduction in PLQY loss, and >2000 h operational stability at 65° C. in air. These improvements were far beyond what either molecule alone was able to achieve, demonstrating a synergy enhancement not predictable from previous approaches to perovskite passivation.

Additional information relating to this Example, including data and information indicated as not shown, may be found in U.S. Provisional Patent Application No. 63/715,373, filed on Nov. 1, 2024, the entire contents of which are incorporated herein by reference.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

Unless otherwise indicated, and in recognition of the inherent nature of the techniques described herein, throughout the present disclosure, terms and phrases such as “absence,” “free,” “does not comprise,” etc. encompass, but do not require a perfect absence of the referenced entity.

Unless otherwise indicated, the term “type” as used herein refers to chemical formula such that a single type means the same chemical formula and different type means different chemical formula. Similarly, use of “more” as in “one or more types” refers to use of different types of the relevant entity.

Unless otherwise indicated, throughout the present disclosure, terms such as “comprising” and the like may be replaced with terms such as “consisting” and the like.

What is claimed is:

1. A perovskite optoelectronic device comprising a perovskite layer comprising a perovskite; and chemical passivating ligands bound to the perovskite of the perovskite layer, wherein the chemical passivating ligands comprise a thioether group, —SR′, wherein R′ is an alkyl group.

2. The perovskite optoelectronic device of claim 1, wherein the alkyl group is unsubstituted.

3. The perovskite optoelectronic device of claim 1, wherein the alkyl group has from 1 to 8 carbon atoms.

4. The perovskite optoelectronic device of claim 1, wherein the alkyl group is a linear alkyl.

5. The perovskite optoelectronic device of claim 1, wherein R′ is methyl.

6. The perovskite optoelectronic device of claim 1, wherein the chemical passivating ligands further comprise a linking group covalently bound to the thioether group and an additional perovskite binding group covalently bound to the linking group.

7. The perovskite optoelectronic device of claim 6, wherein the additional perovskite binding group is an ammonium group, —NH₃⁺.

8. The perovskite optoelectronic device of claim 6, wherein the linking group is an alkyl group.

9. The perovskite optoelectronic device of claim 1, wherein the chemical passivating ligands are selected from those having formula ⁺H₃N—R—SR′, wherein R and R′ are independently selected alkyl groups.

10. The perovskite optoelectronic device of claim 9, wherein R and R′ are independently selected unsubstituted, linear alkyl groups having from 1 to 8 carbon atoms.

11. The perovskite optoelectronic device of claim 1, wherein the chemical passivating ligands are selected from 3-(methylthio)propylammonium, 2-(methylthio)ethylammonium, and combinations thereof.

12. The perovskite optoelectronic device of claim 1, further comprising field-effect passivating ligands bound to the perovskite of the perovskite layer.

13. The perovskite optoelectronic device of claim 12, wherein the field-effect passivating ligands each comprise two ammonium groups.

14. The perovskite optoelectronic device of claim 12, wherein the field-effect passivating ligands are selected from alkyldiammonium compounds.

15. The perovskite optoelectronic device of claim 12, wherein the field-effect passivating ligands are selected from ethane-1,2-diammonium, propane-1,3-diammonium, and combinations thereof.

16. The perovskite optoelectronic device of claim 1 configured as a perovskite solar cell comprising a hole transport layer, an electron transport layer, the perovskite layer between the hole transport layer and the electron transport layer, and the chemical passivating ligands bound to the perovskite of the perovskite layer.

17. The perovskite optoelectronic device of claim 16, further comprising field-effect passivating ligands bound to the perovskite of the perovskite layer.

18. The perovskite optoelectronic device of claim 17, wherein the chemical passivating ligands and the field-effect passivating ligands are located at an interface formed between the electron transport layer and the perovskite layer.

19. The perovskite optoelectronic device of claim 18, wherein the chemical passivating ligands are selected from those having formula ⁺H₃N—R—SR′, wherein R and R′ are independently selected alkyl groups; the field-effect passivating ligands are selected from alkyldiammonium compounds; and the perovskite has formula ABX₃, wherein A is a protonated amine; B is a divalent metal ion; and X is an anion bound to B.

20. The perovskite optoelectronic device of claim 19, wherein the chemical passivating ligands are selected from 3-(methylthio)propylammonium, 2-(methylthio)ethylammonium, and combinations thereof and the field-effect ligands are selected from ethane-1,2-diammonium, propane-1,3-diammonium, and combinations thereof.
